(19) United States
(12) Patent Application Publication
(10) Pub. No.: US 2024/0375682 A1
(43) Pub. Date: Nov. 14, 2024

(54) METHOD OF MAKING HIGHLY HUMANOID SAFE DRIVING DECISION FOR AUTOMATED DRIVING COMMERCIAL VEHICLE

(71) Applicant: Southeast University, Jiangsu (CN)

(72) Inventors: Xu LI, Jiangsu (CN); Weiming HU, Jiangsu (CN); Jinchao HU, Jiangsu (CN); Kun WEI, Jiangsu (CN); Qimin XU, Jiangsu (CN)

(21) Appl. No.: 18/259,378

(22) PCT Filed: Feb. 25, 2022
(86) PCT No.: PCT/CN2022/077923

§ 371 Date: Jun. 26, 2023

(30) Foreign Application Priority Data
Feb. 21, 2022 (CN) 202210158758.2

(51) Int. Cl. B60W 60/00; B60W 50/00

(52) U.S. Cl. CPC B60W 60/0015; B60W 50/0098

(57) ABSTRACT

A method of making a highly humanoid safe driving decision for an automated driving commercial vehicle, includes: collecting synchronously multi-source information on driving behaviors in typical traffic scenarios, constructing an expert trajectory data set representing driving behaviors of excellent drivers; simulating the driving behaviors of excellent drivers by utilizing a generative adversarial imitation learning (GAIL) algorithm, in a comprehensive consideration of influences of factors such as a forward collision, a backward collision, a transverse collision, a vehicle roll stability and a driving smoothness on a driving safety, constructing a generator and a discriminator by utilizing a proximal policy optimization algorithm and a deep neural network respectively, and establishing a safe driving decision-making model with highly humanoid level; and training the safe driving decision-making model to obtain safe driving policies under different driving conditions and to implement an output of an advanced decision-making for the automated driving commercial vehicle.

### TECHNICAL FIELD

The present disclosure relates to a method of making a driving decision for a commercial vehicle, in particular to a method of making a highly humanoid safe driving decision for an automated driving commercial vehicle, which belongs to the technical field of vehicle safety.

### BACKGROUND

Commercial vehicles are the main undertakers of road transportation in China, and are also the major causes of traffic accidents involving death and injury. According to statistics, ultra serious traffic accidents in which more than 10 people are killed once caused by commercial vehicles account for more than 90% of the total number of major road traffic accidents nationwide every year in China, and these accidents seriously threaten our road traffic safety. In order to significantly improve traffic safety and transportation efficiency, automated driving technology of the commercial vehicles with advanced driving assistance and even fully automated driving has been highly concerned and developed in recent years.

Man-machine co-driving is the only way for the development of intelligent vehicles. As a key part of implementing high-quality automated driving, the driving decision-making determines the safety and rationality of automated driving of the commercial vehicles in the process of man-machine co-driving. In the actual traffic environment, in addition to ensure the ability to avoid driving dangers, the ideal automated driving decision-making should also have certain “social intelligence” attributes, that is, understanding the reactions of surrounding human drivers in different situations and making the corresponding “optimal” decisions. However, the existing automated driving policies of the commercial vehicles ignore the “social intelligence” in the driving logic, and their decision-making ability is difficult to match that of human drivers, thereby leading to the mismatch between automated driving vehicles and human drivers, and even to the conflict between automated vehicles and human drivers. The output non-humanoid dangerous driving policies will cause disastrous consequences. Therefore, in the man-machine co-driving environment, how to learn the driving behaviors of excellent drivers, construct a highly humanoid level safe driving decision-making strategy, and ensure the driving safety of automated driving commercial vehicles are the key issues to be solved at present.

“Humanoid” driving decision-making methods have been studied in the existing patent documents, which mainly includes rule-based and learning-based decision-making methods. The rule-based decision-making method is to build a driving policy rule base according to the driving rules, driving experience and the like, and make driving decisions according to the driving states of the vehicles and the policy of the rule base. This kind of method has a clear decision intention and a relatively strong interpretability, but it is difficult to traverse all traffic scenarios and driving conditions, and cannot guarantee the robustness and effectiveness of driving decisions in marginal traffic scenarios.

The learning-based decision method is to obtain the optimal policy under a certain traffic scene by simulating the driving behaviors of excellent drivers, which is a kind of method widely used at present. However, although the above two kinds of methods have made some progress, their research objects are mainly for small passenger vehicles, not involving the “humanoid” driving decision-making research of large commercial vehicles.

Different from the small passenger vehicles, the large commercial vehicles have the characteristics of high center of mass position, large vehicle mass, narrow wheel pitch and the like, thereby resulting in a poor roll stability. When emergency braking, emergency lane change, sharp steering and other operations are performed, it is extremely easy to destabilize and rollover. Therefore, the driving behaviors and operating characteristics of human drivers have great differences when driving commercial vehicles and small passenger vehicles. Compared with small passenger vehicles that only pay attention to collision prevention, large collision vehicles need to take into account of a plurality of aspects such as collision prevention and rollover prevention at the same time.

In general, the existing “humanoid” driving decision-making methods for small passenger vehicles cannot be directly applied to commercial vehicles. The research on safe driving decision-making of automated driving commercial vehicles is relatively scarce, especially the research on safe driving decision-making of vehicles with highly humanoid level is still in a blank state at present.

### SUMMARY

The objectives of the present disclosure: in order to implement the safe driving decision-making of automated driving commercial vehicles with highly humanoid level and ensure the driving safety of vehicles, the present disclosure provides a method of making a highly humanoid safe driving decision for an automated driving commercial vehicle such as a heavy truck, a heavy truck. This method is capable of simulating the driving intentions of excellent human drivers, providing more reasonable and safe driving policies for the automated driving commercial vehicles, and effectively guaranteeing the driving safety of the automated driving commercial vehicles. At the same time, the method does not need to consider the complex vehicle dynamics equation and body parameters, and the calculation method is simple and clear, which is capable of outputting the safe driving policy of the automated driving commercial vehicles in real time, and the sensor cost is low; which is easy to popularize on a large scale.

Technical solutions: in order to realize the objectives of the present disclosure, the technical solutions provided in the present disclosure is a method of making a highly humanoid safe driving decision for an automated driving commercial vehicle. Firstly, multi-source information on driving behaviors in typical traffic scenarios are collected synchronously, and an expert trajectory data set representing driving behaviors of excellent drivers is constructed; secondly, the driving behaviors of excellent drivers are simulated by utilizing a generative adversarial imitation learning (GAIL) algorithm, in a comprehensive consideration of influences of factors such as a forward collision, a backward collision, a transverse collision, a vehicle roll stability and a driving smoothness on a driving safety, a generator and a discriminator are constructed by utilizing a proximal policy optimization algorithm and a deep neural network respectively, and further a safe driving decision-making model with highly humanoid level is established; finally, the safe driving decision-making model is trained to obtain safe driving policies under different driving conditions and to implement an output of an advanced decision-making for the automated driving commercial vehicles; the method specifically comprises the following steps.

In Step 1, the expert trajectory data set representing the driving behaviors of the excellent drivers is constructed.

In order to construct a safe driving decision-making policy for the automated driving commercial vehicle with highly humanoid level, the driving behaviors of the excellent drivers under different driving conditions should be learned. Firstly, heterogeneous multi-sensor information from typical traffic scenes are collected in a time-space global unified coordinate system; secondly, the expert trajectory data set representing the driving behaviors of the excellent drivers are constructed by utilizing the above data.

Specifically, commercial vehicles installed with a plurality of sensors are driven by ten excellent drivers, the installed sensors include an inertial navigation system, a centimeter-level high precision global positioning system (GPS) and a millimeter-wave radar.

In view of the road driving environment in China, in a safe driving stage, data on various typical driving behaviors of the excellent drivers, including a lane change, a lane keeping, a vehicle following, an overtaking, an acceleration and a deceleration are collected and processed, to obtain heterogeneous descriptive data for the various driving behaviors, including: position information, speed information, acceleration information, yaw rates, steering wheel angles, accelerator pedal openings, and brake pedal openings of the commercial vehicles (automated driving vehicles), as well as relative distances, relative speeds and relative accelerations from surrounding vehicles.

In Step 2, the safe driving decision-making model with highly humanoid level is established.

With the enhancement on computing power of on-board computing unit, learning-based decision-making method has been widely concerned. Among them, imitation learning is a learning method characterized by imitating the behavior of experts, which has been applied in automatic driving, robotics, natural language processing and other scenarios. Therefore, the present disclosure utilizes the imitation learning method to learn the expert trajectory data set, that is, to simulate the driving behavior of excellent drivers.

A generative adversarial imitation learning (GAIL) combines the ideas of reinforcement learning and generative adversarial imitation learning, and avoids the difficulty of defining a complete reward function manually by directly learning policies from expert experience, which has certain advantages in improving the effectiveness and reliability of driving decision making. Therefore, the driving behaviors of excellent drivers are simulated by utilizing the generative adversarial imitation learning algorithm in the present disclosure, and the safe driving decision-making model of the automated driving commercial vehicles is constructed, the specific steps are as follows.

In Sub-step 1, a generator network is established.

In order to learn excellent driving behaviors under different driving conditions and generate driving policies as close as possible to the decisions of excellent drivers, a generator is constructed by utilizing a proximal policy optimization algorithm in the present disclosure.

In Sub-step 1.1, basic parameters for the generator network are defined.

### (1) State Space

The state space is composed of two parts: motion states of the automated driving commercial vehicles and motion states of the surrounding vehicles, specific descriptions are as follows:

$${S}_{t} = [ {p}_{x} , {p}_{y} , {v}_{x} , {v}_{y} , {a}_{x} , {a}_{y} , {ω}_{s} , {d}_{rel\_j} , {v}_{rel\_j} , {a}_{rel\_j} ] \qquad ( 1 )$$

where Sₜ represents the state space at the time t, pₓ,p_{y} represent a transverse position and a longitudinal position of the automated driving commercial vehicle, respectively, vₓ,v_{y} represent a transverse velocity and a longitudinal velocity of the automated driving commercial vehicle, respectively, and the units are meters per second, aₓ,a_{y} represent a transverse acceleration and a longitudinal acceleration of the automated driving commercial vehicle, respectively, and the units are meters per quadratic second; ωₛ represents the yaw rate of the automated driving commercial vehicle, and the unit is radians per second; d_{rel_j}, v_{rel_j}, a_{rel_j} represent a relative distance, a relative speed and a relative acceleration between the automated driving commercial vehicle and the j-th vehicle, respectively, and the units are meters, meters per second and meters per quadratic second, respectively, where j represents the serial number of the surrounding vehicles, and j=1, 2, 3, 4, 5, 6, represents vehicles in front of the automated driving commercial vehicle in the current lane, behind the automated driving commercial vehicle in the current lane, in front of the automated driving commercial vehicle in the left lane, behind the automated driving commercial vehicle in the left lane, in front of the automated driving commercial vehicle in the right lane, behind the automated driving commercial vehicle in the right lane.

### (2) Motion Space

In order to output driving policies with clear decision intentions in the present disclosure, the motion space covering transverse and longitudinal driving policies are defined as:

$${A}_{t} = [ {a}_{1} , {a}_{2} , {a}_{3} , {a}_{4} , {a}_{5} , {a}_{6} ] \qquad ( 2 )$$

where Aₜ represents the motion space at the time t, a₁, a₂, a₃ represent the left turn, the straight ahead and the right turn, respectively, a₄, a₅, a₆ represent the acceleration, the maintaining speed and the deceleration, respectively.

### (3) Reward Function

In order to evaluate the advantages and disadvantages of driving policies at every moment and guide the generator to output more reasonable and safe driving policies, a reasonable and comprehensive reward function should be constructed. Considering that the essence of a safe driving decision is a multi-objective optimization problem involving anti-collision, anti-rollover, driving smoothness and other factors, the reward function in the present disclosure is designed as:

$${R}_{t} = {r}_{1} + {r}_{2} + {r}_{3} + {r}_{4} + {r}_{5} + {r}_{6} \qquad ( 3 )$$

where Rₜ represents a total reward function at the time t, r₁, r₂, r₃, r₄, r₅, r₆ represent a forward anti-collision reward function, a backward anti-collision reward function, a side anti-collision reward function, an anti-rollover reward function, a driving smoothness reward function and a penalty function, respectively.

Firstly, in order to avoid a forward collision, a reasonable safety distance is maintained between the automated driving commercial vehicle and the vehicle in front of the same lane, and the forward anti-collision reward function r₁ is defined as:

$${r}_{1} = \{ \begin{matrix}\begin{matrix}{α}_{1} ( {x}_{rel \_ 1} - {D}_{f} ) & {x}_{rel \_ 1} \geq {D}_{f}\end{matrix} \\ \begin{matrix}0 & {x}_{rel \_ 1} < {D}_{f}\end{matrix}\end{matrix} \qquad ( 4 )$$

where D_{f} represents a minimum forward safety distance and the unit is meters, α₁ represents a weight coefficient of the forward anti-collision reward function.

Considering that a reasonable minimum safety distance should take into account both traffic efficiency and traffic safety, a dynamic minimum forward safety distance is designed by utilizing a time headway in the present disclosure, that is:

$${D}_{f} = {v}_{y} \cdot {β}_{T H} + \vert {v}_{y} - {v}_{rel \_ 1} \vert \cdot T + {L}_{min} \qquad ( 5 )$$

where β_{TH} represents the time headway and the unit is seconds, T represents a data sampling frequency and the unit is seconds, and Lₘᵢₙ is a critical distance and the unit is meters.

Similarly, in order to avoid the backward collision, a reasonable safe distance is maintained between the automated driving commercial vehicle and the vehicle behind the same lane; and the backward anti-collision reward function r₂ is defined as:

$${r}_{2} = \{ \begin{matrix}\begin{matrix}{α}_{2} ( {x}_{rel \_ 2} - {D}_{b} ) & {x}_{rel \_ 2} \geq {D}_{b}\end{matrix} \\ \begin{matrix}0 & {x}_{rel \_ 2} < {D}_{b}\end{matrix}\end{matrix} \qquad ( 6 )$$

where D_{b} represents a minimum backward safety distance and a unit is meters, α₂ represents a weight coefficient of the backward anti-collision reward function, and x_{rel_2} represents a relative distance between the automated driving commercial vehicle and the vehicle behind the current lane and the unit is meters.

In order to avoid the transverse collision, reasonable safe distances are maintained between the automated driving commercial vehicle and the vehicle in the left lane and the vehicle in the right lane; the side anti-collision reward function r₃ is defined as:

$${r}_{3} = \{ \begin{matrix}\begin{matrix}{\sum }_{i = 3}^{6} {α}_{3} ( {x}_{rel \_ j} - {D}_{s} ) & {x}_{rel \_ j} \geq {D}_{s}\end{matrix} \\ \begin{matrix}0 & {x}_{rel \_ j} < {D}_{s}\end{matrix}\end{matrix} \qquad ( 7 )$$

where Dₛ represents a minimum side safety distance and the unit is meters, and

$${D}_{s} = 0.94 + \frac{3.6 \cdot {v}_{y} - 40}{200} ,$$

α₃ represents a weight coefficient of the side anti-collision reward function.

Secondly, in the process of curve running, braking deceleration and lane changing, with a purpose of avoiding a rollover accident, the automated driving commercial vehicle is maintained at a reasonable transverse acceleration, and the anti-rollover reward function r₄ is defined as:

$${r}_{4} = \{ \begin{matrix}\begin{matrix}{α}_{4} ( {a}_{thr} - {a}_{x} ) & {a}_{x} \leq {a}_{thr}\end{matrix} \\ \begin{matrix}0 & {a}_{x} > {a}_{thr}\end{matrix}\end{matrix} \qquad ( 8 )$$

where aₜₕᵣ represents a threshold of the transverse acceleration of the automated driving commercial vehicle, and the unit is meters per quadratic second, α₄ represents a weight coefficient of the anti-rollover reward function.

Thirdly, considering that a reasonable safe driving decision should not only ensure the driving safety, but also have a better driving smoothness and comfort, the driving smoothness reward function r₅ is defined as:

$${r}_{5} = - {α}_{5} \cdot {\dot{a}}_{x} - {α}_{6} \cdot {\dot{a}}_{y} \qquad ( 9 )$$

where \dot{a}ₓ,\dot{a}_{y} represent a transverse jerk and a longitudinal jerk of the automated driving commercial vehicle respectively, and units are meters per cubic second, α₅,α₆ represent weight coefficients of the driving smoothness reward function.

Eventually, by means of applying a negative feedback to avoid driving policies leading to the collision and the rollover accidents, the penalty function r₆ is defined as:

$${r}_{6} = \{ \begin{matrix} & - 200 a rollover occurred by the automated driving commerical vehicle \\ & - 200 a collosion occurred by the automated driving commerical vehicle \\ 0 & no rollover or collision occurred by the automated driving commerical vehicle\end{matrix} . \qquad ( 10 )$$

In Sub-step 1.2, a generator network based on “actor-critic” is established.

The generator network including a policy network and a criticism network is established by utilizing the “actor-critic” framework. In the policy network, the state space information is taken as an input, and a motion decision, namely, the driving policies of the automated driving commercial vehicle are output; in the criticism network, the state space information and the motion decision are taken as inputs and the value for the current “state-motion” is output. The contents are specifically as follows.

### (1) The Policy Network Part of the Generator is Designed

The policy network is established by utilizing a neural network with a plurality of fully connected layers, firstly, the normalized state quantity Sₜ is input into an input layer F₁, a fully connected layer F₂ and a fully connected layer F₃ successively to obtain an output O₁, namely, the motion space Aₜ.

Considering that the dimension of the state space is 25, the number of neurons in the state input layer is set to be 25, the number of neurons in the fully connected layer F₁ and the fully connected layer F₂ are set to be 128 and 64 respectively, and the activation functions of the fully connected layer F₁ and the fully connected layer F₂ are S-type functions, the expression is

$$s ( x ) = \frac{1}{1 + {e}^{- x}} .$$

### (2) The Criticism Network Part of the Generator is Designed

The criticism network is established by utilizing the neural network with the plurality of fully connected layers, the normalized state quantity Sₜ and the motion space Aₜ are input into a fully connected layer F₄ and a fully connected layer F₅ successively to obtain an output O₂, namely, the Q function value Q(Sₜ,Aₜ).

The number of neurons in the fully connected layer F₄ and the fully connected layer F₅ are set to be 128 and 64 respectively, and the activation functions of both layers are S-type functions.

In Sub-step 2, a discriminator network is established.

The discriminator takes the expert experience trajectory and the policy trajectory of the generator as inputs, and a driving policy score Pₜ(τ) is output by determining differences between generated driving policies and the driving behaviors of the excellent drivers, thereby implementing the optimization of the generator; considering that the deep neural network has a strong nonlinear fitting ability, a strong processing ability of high dimensional data and a strong feature extraction ability of the deep neural network, the present disclosure utilizes the deep neural network to establish the discriminator.

Specifically, the discriminator is established by utilizing the neural network with the plurality of fully connected layers, the discriminator contains three fully connected layers, F6, F7 and F8, the excitation function of each fully connected layer adopts the linear rectification function, the expression is f(x)=max(0,x).

In Step 3, the safe driving decision-making model of the automated driving commercial vehicles is trained.

In order to maximize the cumulative returns related to the policy parameters, the GAIL algorithm is utilized to update the parameters for the safe driving decision-making model; the process of policy updating includes two stages, namely, the imitation learning stage and the reinforcement learning stage.

In the imitation learning stage, the discriminator optimizes the driving policies output by the generator by means of scoring, meanwhile, the discriminator takes differences between the data generated by the network and the expert data as bases for optimizing the policy network; in the reinforcement learning stage, the criticism network guides the learning direction of the safe driving decision-making model according to the changes of the reward function, and further implements the optimization of the driving policies output by the generator. The parameter updating method is specifically as follows.

In Sub-step 1, τ_{E}:π_{E} is initialized, the policy parameter θ₀, the value function parameter ϕ₀, and the discriminator parameter ω₀ are initialized.

τ_{E} represents the expert trajectory data set constructed in Step 1 to represent the driving behaviors of excellent drivers, and τ_{E}={(S₁,A₁,R₁),(S₂,A₂,R₂), . . . , (Sₙ,Aₙ,Rₙ)}; π_{E} represents the driving policy distribution corresponding to an expert trajectory τ_{E}.

In Sub-step 2, a 20,000 iterative solution is performed, each iteration includes Sub-step 2.1 to Sub-step 2.5, which is specifically as follows.

In Sub-step 2.1, the driving trajectory τ′_{E} is generated by the policy network to form the trajectory set Pₜ expressed as Pₜ={τ′_{E}}.

In Sub-step 2.2, the expert trajectory is sampled, the “track-policy distribution” after sampling is expressed as τᵢ:π₇₄ _{ᵢ}.

In Sub-step 2.3, the network parameters for the discriminator are updated by utilizing the gradient ∇_{cri},

$${∇}_{cri} = {\hat{E}}_{{τ}_{i}} [ {∇}_{t} log ( {P}_{t} ( {S}_{t} , {A}_{t} ) ) ] + {\hat{E}}_{{τ}_{E}} [ {∇}_{t} log ( 1 - {P}_{t} ( {S}_{t} , {A}_{t} ) ) ] , \qquad ( 11 )$$

where Pₜ(Sₜ,Aₜ) represents an output of the discriminator at the time t, namely, the probability that the current trajectory is the expert trajectory; Ê_{τ}_{ᵢ} represents the average reward of generating the driving trajectory; ∇ₜ represents the gradient at the time t; Ê_{τ}_{_{E}} represents the average reward obtained by the expert trajectory.

In Sub-step 2.4, the policy network parameter is updated.

In Sub-step 2.5, the value function parameter is updated by utilizing the Formula (12),

$${ϕ}_{t + 1} = arg {min}_{ϕ} \frac{1}{\vert {P}_{t} ( {S}_{t} , {A}_{t} ) \vert \cdot T} {\sum }_{{τ}_{E} ∈ {P}_{t}} {{\sum }_{t = 0}^{T} [ {V}_{ϕ} ( {S}_{t} ) - {\hat{R}}_{t} ]}^{2} \qquad ( 12 )$$

where ϕₜ₊₁ represents the value function parameter at the time t+1, V_{ϕ}(Sₜ) represents the value function when the state space is Sₜ, and \hat{R}ₜ represents the reward function to be performed at the time t.

In Sub-step 3, when the number of training iterations reaches 20,000, the loop is terminated.

In Sub-step 4, the safe driving decision-making model is utilized to output the decision policies.

After the training of the safe driving decision-making model is completed, the state space information collected by the sensors are input into the safe driving decision-making model, the advanced driving decision such as the steering, the acceleration, and the deceleration are output reasonably and safely, thereby implementing the safe driving decision of a vehicle with highly humanoid level and effectively ensuring the driving safety of the automated driving commercial vehicles.

The beneficial effects: compared with the general driving decision-making methods, the method provided in the present disclosure has the characteristics of being more effective and reliable, which is specifically as follows.
(1) The method provided in the present disclosure is capable of simulating the driving intentions of the excellent human drivers, providing more reasonable and safe driving policies for the automated driving commercial vehicles, implementing the safe driving decision of the automated driving commercial vehicle with highly humanoid level, and effectively guaranteeing the driving safety of the vehicles.
(2) The method provided in the present disclosure comprehensively considers the influences of factors such as a forward collision, a backward collision, a transverse collision, a vehicle roll stability and a driving smoothness on driving safety, and the safety distance threshold can be adjusted online, which implements the safe driving decision under different driving conditions, and further improves the effectiveness and reliability of decision-making.
(3) The method provided in the present disclosure does not need to consider the complex vehicle dynamics equation and body parameters, and the calculation method is simple and clear, which can output the safe driving policy of the automated driving commercial vehicles in real time, and the used sensor is of a low cost and convenient for a large-scale popularization.

### BRIEF DESCRIPTION OF THE DRAWINGS

FIG. 1 illustrates a technical roadmap in the present disclosure.

FIG. 2 illustrates a schematic diagram of a policy network designed in the present disclosure.

FIG. 3 illustrates a schematic diagram of a criticism network designed in the present disclosure.

FIG. 4 illustrates a schematic diagram of a discriminator network designed in the present disclosure.

### DETAILED DESCRIPTION OF THE EMBODIMENTS

The technical solutions of the present disclosure are further explained in combination of the drawings and embodiments.

Commercial vehicles are the main undertakers of road transportation in China, and are also the major causes of traffic accidents involving death and injury. According to statistics, ultra serious traffic accidents in which more than 10 people are killed once caused by commercial vehicles account for more than 90% of the total number of major road traffic accidents nationwide every year in China, and these accidents seriously threaten our road traffic safety. In order to significantly improve traffic safety and transportation efficiency, automated driving technology of the commercial vehicles with advanced driving assistance and even fully automated driving has been highly concerned and developed in recent years.

Man-machine co-driving is the only way for the development of intelligent vehicles. As a key part of implementing high-quality automated driving. the driving decision-making determines the safety and rationality of automated driving of the commercial vehicles in the process of man-machine co-driving. In the actual traffic environment, in addition to ensure the ability to avoid driving dangers, the ideal automated driving decision-making should also have certain “social intelligence” attributes, that is, understanding the reactions of surrounding human drivers in different situations and making the corresponding “optimal” decisions. However, the existing automated driving policies of the commercial vehicles ignore the “social intelligence” in the driving logic, and their decision-making ability is difficult to match that of human drivers, thereby leading to the mismatch between automated driving vehicles and human drivers, and even to the conflict between automated vehicles and human drivers. The output non-humanoid dangerous driving policies will cause disastrous consequences. Therefore, in the man-machine co-driving environment, how to learn the driving behaviors of excellent drivers, construct a highly humanoid level safe driving decision-making strategy, and ensure the driving safety of automated driving commercial vehicles are the key issues to be solved at present.

“Humanoid” driving decision-making methods have been studied in the existing patent documents, which mainly includes rule-based and learning-based decision-making methods. The rule-based decision-making method is to build a driving policy rule base according to the driving rules, driving experience and the like, and make driving decisions according to the driving states of the vehicles and the policy of the rule base. This kind of method has a clear decision intention and a relatively strong interpretability, but it is difficult to traverse all traffic scenarios and driving conditions, and cannot guarantee the robustness and effectiveness of driving decisions in marginal traffic scenarios.

The learning-based decision method is to obtain the optimal policy under a certain traffic scene by simulating the driving behaviors of excellent drivers, which is a kind of method widely used at present. However, although the above two kinds of methods have made some progress, their research objects are mainly for small passenger vehicles, not involving the “humanoid” driving decision-making research of large commercial vehicles.

Different from the small passenger vehicles, the large commercial vehicles have the characteristics of high center of mass position, large vehicle mass, narrow wheel pitch and the like, thereby resulting in a poor roll stability. When emergency braking, emergency lane change, sharp steering and other operations are performed, it is extremely easy to destabilize and rollover. Therefore, the driving behaviors and operating characteristics of human drivers have great differences when driving commercial vehicles and small passenger vehicles. Compared with small passenger vehicles that only pay attention to collision prevention, large collision vehicles need to take into account of a plurality of aspects such as collision prevention and rollover prevention and other aspects at the same time.

In general, the existing “humanoid” driving decision-making methods for small passenger vehicles cannot be directly applied to commercial vehicles. The research on safe driving decision-making of automated driving commercial vehicles is relatively scarce, especially the research on safe driving decision-making of vehicles with highly humanoid level is still in a blank state at present.

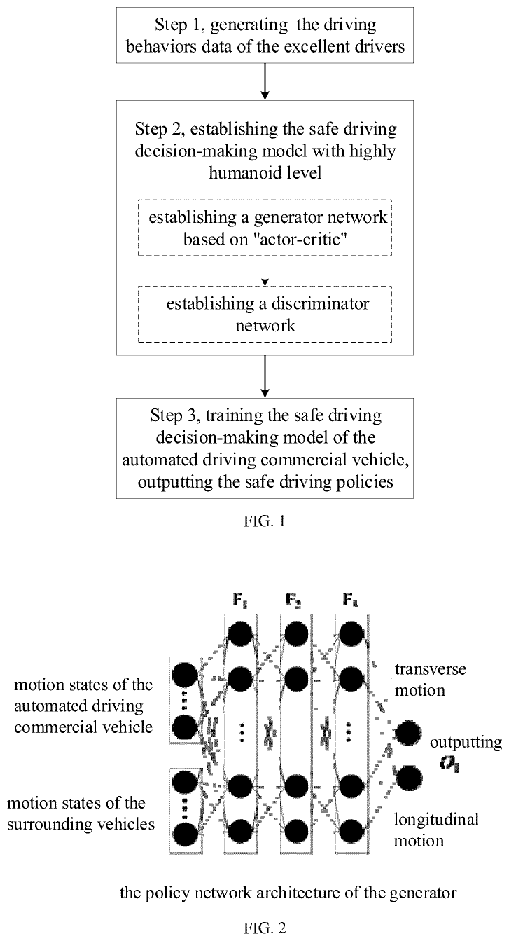

In order to solve the above problems, the present disclosure provides a safe driving decision-making method with highly humanoid level for heavy trucks, heavy trucks and other automated driving commercial vehicles. Firstly, multi-source information on driving behaviors in typical traffic scenarios are collected synchronously, and an expert trajectory data set representing driving behaviors of excellent drivers is constructed. Secondly, the driving behaviors of excellent drivers are simulated by utilizing the generative adversarial imitation learning (GAIL) algorithm, in a comprehensive consideration of influences of factors such as the forward collision, the backward collision, the transverse collision, the vehicle roll stability and the driving smoothness and comfort on the driving safety, a generator and a discriminator are constructed by utilizing the proximal policy optimization algorithm and the deep neural network respectively, and further a safe driving decision-making model with highly humanoid level is established. Finally, the safe driving decision-making model is trained to obtain safe driving policies under different driving conditions and to implement an output of an advanced decision-making for the automated driving commercial vehicles. The method provided in the present disclosure is capable of simulating the driving intentions of the excellent human drivers, providing more reasonable and safe driving policies for the automated driving commercial vehicles, and effectively guaranteeing the driving safety of the automated driving commercial vehicles. The technical route of the present disclosure is as illustrated in FIG. 1, and the specific steps are as follows.

In Step 1, the expert trajectory data set representing the driving behaviors of the excellent drivers is constructed.

In order to construct safe driving decision-making policies for the automated driving commercial vehicles with highly humanoid level, the driving behaviors of the excellent drivers under different driving conditions should be learned. Firstly, heterogeneous multi-sensor information from typical traffic scenes are collected in a time-space global unified coordinate system; secondly, the expert trajectory data set representing the driving behaviors of the excellent drivers are constructed by utilizing the above data.

Specifically, commercial vehicles installed with a plurality of sensors are driven by ten excellent drivers, the installed sensors include an inertial navigation system, a centimeter-level high precision global positioning system (GPS) and a millimeter-wave radar.

In view of the road driving environment in China, in a safe driving stage, data on various typical driving behaviors of the excellent drivers, including the lane change, the lane keeping, the vehicle following, the overtaking, the acceleration and the deceleration are collected and processed, to obtain heterogeneous descriptive description data for the various driving behaviors, including: position information, speed information, acceleration information, yaw rates, steering wheel angles, accelerator pedal openings, and brake pedal openings of the commercial vehicles (automated driving vehicles), as well as relative distances, relative speeds and relative accelerations from surrounding vehicles.

In Step 2, the safe driving decision-making model with highly humanoid level is established.

With the enhancement on computing power of on-board computing unit, learning-based decision-making method has been widely concerned. Among them, imitation learning is a learning method characterized by imitating the behavior of experts, which has been applied in automatic driving, robotics, natural language processing and other scenarios. Therefore, the present disclosure utilizes the imitation learning method to learn the expert trajectory data set, that is, to simulate the driving behavior of excellent drivers.

The Imitative learning mainly includes three kinds of methods, namely, the behavioral cloning, the reverse reinforcement learning and the generative adversarial imitation learning. The behavior cloning is to learn the mapping of state to action from a large number of sample data through a supervised learning. This kind of method is relatively simple and effective in some scenarios, but it is always affected by a state drift. Once encountering states that do not appear in the expert trajectory, it will cause significant errors. Reverse reinforcement learning is a method of learning a return function from expert trajectories and utilizing the return function for strategy estimation. This kind of method avoids the problem of a single step decision error accumulation in behavioral cloning methods, but it has some disadvantages such as a high calculation cost, easy to cause an overfitting.

The generative adversarial imitation learning (GAIL) combines the ideas of reinforcement learning and generative adversarial imitation learning, and avoids the difficulty of defining a complete reward function manually by directly learning policies from expert experience, which has certain advantages in improving the effectiveness and reliability of driving decision making. Therefore, the driving behaviors of excellent drivers are simulated by utilizing the generative adversarial imitation learning algorithm in the present disclosure, and the safe driving decision-making model of the automated driving commercial vehicles is constructed, the specific steps are as follows.

In Sub-step 1, the generator network is established.

In order to learn excellent driving behaviors under different driving conditions and generate driving policies as close as possible to the decisions of excellent drivers, a generator is constructed by utilizing the proximal policy optimization algorithm in the present disclosure. Considering that the proximal policy optimization (PPO) algorithm combines advantages of the advantage actor critic (A2C) and the trust region policy optimization (TRPO) algorithm, and avoids an excessive updating by a clipping method, which can effectively improve the convergence speed and stability of generator network. Therefore, the PPO algorithm is adopted in the present disclosure to construct the generator.

In Sub-step 1.1, basic parameters for the generator network are defined.

### (1) State Space

The state space is composed of two parts: motion states of the automated driving commercial vehicles and motion states of the surrounding vehicles, specific descriptions are as follows:

$${S}_{t} = [ {p}_{x} , {p}_{y} , {v}_{x} , {v}_{y} , {a}_{x} , {a}_{y} , {ω}_{s} , {d}_{rel \_ j} , {v}_{rel \_ j} , {a}_{rel \_ j} ] , \qquad ( 1 )$$

where Sₜ represents the state space at the time t, pₓ,p_{y} represent a transverse position and a longitudinal position of the automated driving commercial vehicle, respectively, vₓ,v_{y} represent a transverse velocity and a longitudinal velocity of the automated driving commercial vehicle, respectively, and the units are meters per second, aₓ,a_{y} represent a transverse acceleration and a longitudinal acceleration of the automated driving commercial vehicle, respectively, and the units are meters per quadratic second; ωₛ represents the yaw rate of the automated driving commercial vehicle, and the unit is radians per second; d_{rel_j}, v_{rel_j}, a_{rel_j} represent a relative distance, a relative speed and a relative acceleration between the automated driving commercial vehicle and the j-th vehicle, respectively, and the units are meters, meters per second and meters per quadratic second, respectively, where j represents the serial number of the surrounding vehicles, and j=1, 2, 3, 4, 5, 6, represents vehicles in front of the automated driving commercial vehicle in the current lane, behind the automated driving commercial vehicle in the current lane, in front of the automated driving commercial vehicle in the left lane, behind the automated driving commercial vehicle in the left lane, in front of the automated driving commercial vehicle in the right lane, behind the automated driving commercial vehicle in the right lane.

### (2) Motion Space

In order to output driving policies with clear decision intentions in the present disclosure, the motion space covering transverse and longitudinal driving policies are defined as:

$${A}_{t} = [ {a}_{1} , {a}_{2} , {a}_{3} , {a}_{4} , {a}_{5} , {a}_{6} ] , \qquad ( 2 )$$

where Aₜ represents the motion space at the time t, a₁, a₂, a₃ represent the left turn, the straight ahead and the right turn, respectively, a₄, a₅, a₆ represent the acceleration, the maintaining speed and the deceleration, respectively.

### (3) Reward Function

In order to evaluate the advantages and disadvantages of driving policies at every moment and guide the generator to output more reasonable and safe driving policies, a reasonable and comprehensive reward function should be constructed. Considering that the essence of safe driving decision is a multi-objective optimization problem involving anti-collision, anti-rollover, driving smoothness and comfort and other factors, the reward function in the present disclosure is designed as:

$${R}_{t} = {r}_{1} + {r}_{2} + {r}_{3} + {r}_{4} + {r}_{5} + {r}_{6} , \qquad ( 3 )$$

where Rₜ represents a total reward function at the time t, r₁, r₂, r₃, r₄, r₅, r₆ represent a forward anti-collision reward function, a backward anti-collision reward function, a side anti-collision reward function, an anti-rollover reward function, a driving smoothness reward function and a penalty function, respectively.

Firstly, in order to avoid a forward collision, a reasonable safety distance is maintained between the automated driving commercial vehicle and the vehicle in front of the same lane, and the forward anti-collision reward function r₁ is defined as:

$${r}_{1} = \{ \begin{matrix}{α}_{1} ( {x}_{rel \_ 1} - {D}_{f} ) & {x}_{rel \_ 1} \geq {D}_{f} \\ 0 & {x}_{rel \_ 1} < {D}_{f}\end{matrix} , \qquad ( 4 )$$

where D_{f} represents a minimum forward safety distance and the unit is meters, α₁ represents a weight coefficient of the forward anti-collision reward function.

Considering that a reasonable minimum safety distance should take into account both traffic efficiency and traffic safety, a dynamic minimum forward safety distance is designed by utilizing a time headway in the present disclosure, that is:

$${D}_{f} = {v}_{y} \cdot {β}_{TH} + \vert {v}_{y} - {v}_{rel \_ 1} \vert \cdot T + {L}_{min} , \qquad ( 5 )$$

where β_{TH} represents the time headway and the unit is seconds, T represents a data sampling frequency and the unit is seconds, and Lₘᵢₙ is a critical distance and the unit is meters.

Similarly, in order to avoid the backward collision, a reasonable safe distance is maintained between the automated driving commercial vehicle and the vehicle behind the same lane: and the backward anti-collision reward function r₂ is defined as:

$${r}_{2} = \{ \begin{matrix}{α}_{2} ( {x}_{rel \_ 2} - {D}_{b} ) & {x}_{rel \_ 2} \geq {D}_{b} \\ 0 & {x}_{rel \_ 2} < {D}_{b}\end{matrix} , \qquad ( 6 )$$

where D_{b} represents a minimum backward safety distance and the unit is meters, α₂ represents a weight coefficient of the backward anti-collision reward function, and x_{rel_2} represents a relative distance between the automated driving commercial vehicle and the vehicle behind the current lane and the unit is meters.

In order to avoid the transverse collision, reasonable safe distances are maintained between the automated driving commercial vehicle and the vehicle in the left lane and the vehicle in the right lane; therefore, the side anti-collision reward function r₃ is defined as:

$${r}_{3} = \{ \begin{matrix}{\sum }_{i = 3}^{6} {α}_{3} ( {x}_{rel \_ j} - {D}_{s} ) & {x}_{rel \_ j} \geq {D}_{s} \\ 0 & {x}_{rel \_ j} < {D}_{s}\end{matrix} , \qquad ( 7 )$$

where Dₛ represents a minimum side safety distance and the unit is meters, and

$${D}_{s} = 0.94 + \frac{3.6 \cdot {v}_{y} - 40}{200} ,$$

α₃ represents a weight coefficient of the side anti-collision reward function.

Secondly, in the process of curve running, braking deceleration and lane changing, with a purpose of avoiding a rollover accident, the automated driving commercial vehicle is maintained at a reasonable transverse acceleration, and the anti-rollover reward function r₄ is defined as:

$${r}_{4} = \{ \begin{matrix}{α}_{4} ( {a}_{thr} - {a}_{x} ) & {a}_{x} \leq {a}_{thr} \\ 0 & {a}_{x} > {a}_{thr}\end{matrix} , \qquad ( 8 )$$

where aₜₕᵣ represents a threshold of the transverse acceleration of the automated driving commercial vehicle, and the unit is meters per quadratic second, α₄ represents a weight coefficient of the side anti-rollover reward function.

Thirdly, considering that a reasonable safe driving decisions should not only ensure the driving safety, but also have a better driving smoothness and comfort, the driving smoothness reward function r₅ is defined as:

$${r}_{5} = - {α}_{5} \cdot {\dot{a}}_{x} - {α}_{6} \cdot {\dot{a}}_{y} , \qquad ( 9 )$$

where \dot{a}ₓ,\dot{a}_{y} represent a transverse jerk and a longitudinal jerk of the automated driving commercial vehicle respectively, and the units are meters per cubic second, α₅,α₆ represent weight coefficients of the driving smoothness reward function.

Eventually, by means of applying a negative feedback to avoid driving policies leading to the collision and the rollover accidents, the penalty function r₆ is defined as:

$${r}_{6} = \{ \begin{matrix}- 200 & the rollover occurred by the automated driving commercial vehicle \\ - 200 & the collision occurred by the automated driving commercial vehicle \\ 0 & no rollover or collision occurred by the automated driving commercial vehicle\end{matrix} . \qquad ( 10 )$$

In Sub-step 1.2, a generator network based on “actor-critic” is established.

The generator network including the policy network and the criticism network is established by utilizing the “actor-critic” framework. In the policy network, the state space information is taken as the input, motion decisions, namely, the driving policies of the automated driving commercial vehicle are output; in the criticism network, the state space information and the motion decisions are taken as inputs and the value for the current “state-motion” is output. The contents are specifically as follows.

### (1) The Policy Network Part of the Generator is Designed

The policy network is established by utilizing a neural network with a plurality of fully connected layers, and the specific network architecture is illustrated in FIG. 2. Firstly, the normalized state quantity Sₜ is input into an input layer F₁, a fully connected layer F₂ and a fully connected layer F₃ successively to obtain an output O₁, namely, the motion space Aₜ.

Considering that the dimension of the state space is 25, the number of neurons in the state input layer is set to be 25, the number of neurons in the fully connected layer F₁ and the fully connected layer F₂ are set to be 128 and 64 respectively, and the activation functions of the fully connected layer F₁ and the fully connected layer F₂ are S-type functions, the expression is

$$s ( x ) = \frac{1}{1 + {e}^{- x}} .$$

### (2) The Criticism Network Part of the Generator is Designed

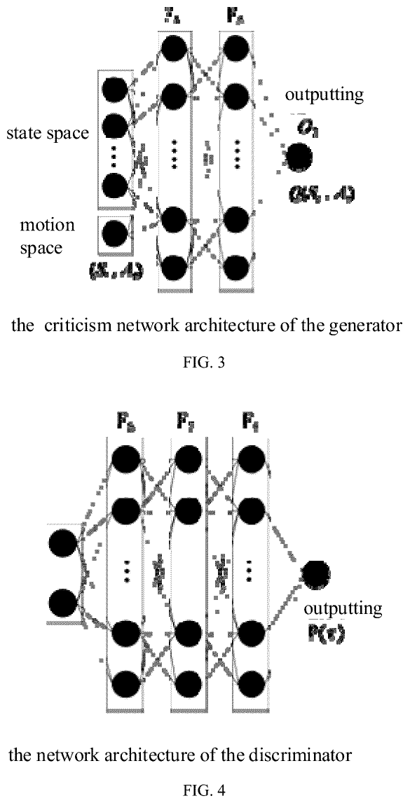

The criticism network is established by utilizing the neural network with the plurality of fully connected layers, and the specific network architecture is illustrated in FIG. 3. The normalized state quantity Sₜ and the motion space Aₜ are input into a fully connected layer F₄ and a fully connected layer F₅ successively to obtain an output O₂, namely, the Q function value Q(Sₜ,Aₜ).

The number of neurons in the fully connected layer F₄ and the fully connected layer F₅ are set to be 128 and 64 respectively, and the activation functions of both layers are S-type functions.

In Sub-step 2, the discriminator network is established.

The discriminator takes the expert experience trajectory and the policy trajectory of the generator as inputs, and a driving policy score Pₜ(τ) is output by determining the differences between generated driving policies and the driving behaviors of the excellent drivers, thereby implementing the optimization of the generator; considering that the deep neural network has a strong nonlinear fitting ability, a strong processing ability of high dimensional data and a strong feature extraction ability of the deep neural network, the present disclosure utilizes the deep neural network to establish the discriminator.

Specifically, the discriminator is established by utilizing the neural network with the plurality of fully connected layers. As illustrated in FIG. 4, the discriminator contains three fully connected layers, F6, F7 and F8, the excitation function of each fully connected layer adopts the linear rectification function, the expression is f(x)=max(0,x).

In Step 3, the safe driving decision-making model of the automated driving commercial vehicles is trained.

In order to maximize the cumulative returns related to the policy parameters, the GAIL algorithm is utilized to update the parameters for the safe driving decision-making model; the process of policy updating includes two stages, namely, the imitation learning stage and the reinforcement learning stage.

In the imitation learning stage, the discriminator optimizes the driving policies output by the generator by means of scoring, meanwhile, the discriminator takes differences between the data generated by the network and the expert data as bases for optimizing the policy network; in the reinforcement learning stage, the criticism network guides the learning direction of the safe driving decision-making model according to the changes of the reward functions, and further implements the optimization of the driving policies output by the generator. The specific parameter updating method is as follows.

In Sub-step 1, τ_{E}:π_{E} is initialized, the policy parameter θ₀, the value function parameter ϕ₀, and the discriminator parameter ω₀ are initialized.

τ_{E} represents the expert trajectory data set constructed in Step 1 to represent the driving behaviors of excellent drivers, and τ_{E}={(S₁,A₁,R₁),(S₂,A₂,R₂), . . . , (Sₙ,Aₙ,Rₙ)}; π_{E} represents the driving policy distribution corresponding to an expert trajectory τ_{E}.

In Sub-step 2, a 20,000 iterative solution is performed, each iteration includes Sub-step 2.1 to Sub-step 2.5, which is specifically as follows.

In Sub-step 2.1, the driving trajectory τ′_{E} is generated by the policy network to form the trajectory set Pₜ expressed as Pₜ={τ′_{E}}.

In Sub-step 2.2, the expert trajectory is sampled, the “track-policy distribution” after sampling is expressed as τᵢ:π_{θ}_{ᵢ}.

In Sub-step 2.3, the network parameters for the discriminator are updated by utilizing the gradient ∇_{cri},

$${∇}_{cri} = {\hat{E}}_{{τ}_{i}} [ {∇}_{t} log ( {P}_{t} ( {S}_{t} , {A}_{t} ) ) ] + {\hat{E}}_{{τ}_{E}} [ {∇}_{t} log ( 1 - {P}_{t} ( {S}_{t} , {A}_{t} ) ) ] , \qquad ( 11 )$$

where Pₜ(Sₜ,Aₜ) represents an output of the discriminator at the time t, namely, the probability that the current trajectory is the expert trajectory; Ê_{τ}_{ᵢ} represents the average reward of generating the driving trajectory; ∇ₜ represents the gradient at the time t; Ê_{τ}_{_{E}} represents the average reward obtained by the expert trajectory.

In Sub-step 2.4, the policy network parameter is updated.

In Sub-step 2.5, the value function parameter is updated by utilizing the Formula (12),

$${ϕ}_{t + 1} = arg {min}_{ϕ} \frac{1}{\vert {P}_{t} ( {S}_{t} , {A}_{t} ) \vert \cdot T} {\sum }_{{τ}_{E} ∈ {P}_{t}} {{\sum }_{t = 0}^{T} [ {V}_{ϕ} ( {S}_{t} ) - {\hat{R}}_{t} ]}^{2} , \qquad ( 12 )$$

where ϕₜ₊₁ represents the value function parameter at the time t+1, V_{ϕ}(Sₜ) represents the value function when the state space is Sₜ, and \hat{R}ₜ represents the reward function to be performed at the time t.

In Sub-step 3, when the number of training iterations reaches 20,000, the loop is terminated.

In Sub-step 4, the safe driving decision-making model is utilized to output the decision policies.

After the training of the safe driving decision-making model is completed, the state space information collected by the sensors are input into the safe driving decision-making model, the advanced driving decisions such as the steering, the acceleration, the deceleration are output reasonably and safely, thereby implementing the safe driving decisions of vehicles with highly humanoid level and effectively ensuring the driving safety of the automated driving commercial vehicles.

What is claimed is:

1. A method of making a highly humanoid safe driving decision for an automated driving commercial vehicle, comprising: firstly, collecting multi-source information on driving behaviors in typical traffic scenarios synchronously, and constructing an expert trajectory data set representing driving behaviors of excellent drivers; secondly, simulating, by utilizing a generative adversarial imitation learning (GAIL) algorithm, the driving behaviors of the excellent drivers, in a comprehensive consideration of influences of factors such as a forward collision, a backward collision, a transverse collision, a vehicle roll stability, and a driving smoothness on a driving safety, constructing, by utilizing a proximal policy optimization algorithm and a deep neural network respectively, a generator and a discriminator, and further establishing a safe driving decision-making model with highly humanoid level; finally, training the safe driving decision-making model to obtain safe driving policies under different driving conditions and to implement an output of an advanced decision-making for the automated driving commercial vehicle; wherein the method specifically includes following steps:
Step 1, constructing the expert trajectory data set representing the driving behaviors of the excellent drivers;
firstly, collecting, in a time-space global unified coordinate system, heterogeneous multi-sensor information from typical traffic scenes; secondly, constructing, by utilizing the collected multi-sensor information, the expert trajectory data set representing the driving behaviors of the excellent drivers;
specifically, driving, by ten excellent drivers, commercial vehicles installed with a plurality of sensors wherein the installed sensors include an inertial navigation system, a centimeter-level high precision global positioning system and a millimeter-wave radar;
in a safe driving stage, collecting and processing data on various typical driving behaviors of the excellent drivers, including a lane change, a lane keeping, a vehicle following, an overtaking, an acceleration and a deceleration, to obtain heterogeneous descriptive data for the various driving behaviors, including: position information, speed information, acceleration information, yaw rates, steering wheel angles, accelerator pedal openings, and brake pedal openings of the automated driving commercial vehicle, as well as relative distances, relative speeds and relative accelerations from surrounding vehicles;
Step 2, establishing the safe driving decision-making model with highly humanoid level;
simulating, by utilizing the Generative Adversarial Imitation Learning (GAIL), the driving behaviors of the excellent drivers, and constructing the safe driving decision-making model of the automated driving commercial vehicle, steps are specifically as follows:
Sub-step 1, establishing a generator network;
establishing, by the proximal policy optimization algorithm, the generator;
Sub-step 1.1, defining basic parameters for the generator network;
(1) a state space
the state space being composed of two parts, namely, motion states of the automated driving commercial vehicle and motion states of the surrounding vehicles, descriptions being specifically as follows:
$${S}_{t} = [ {p}_{x} , {p}_{y} , {v}_{x} , {v}_{y} , {a}_{x} , {a}_{y} , {ω}_{s} , {d}_{rel \_ j} , {v}_{rel \_ j} , {a}_{rel \_ j} ] \qquad ( 1 )$$
where Sₜ represents a state space at a time t, pₓ, p_{y} represent a transverse position and a longitudinal position of the automated driving commercial vehicle, respectively, vₓ,v_{y} represent a transverse velocity and a longitudinal velocity of the automated driving commercial vehicle, respectively, and units are meters per second; aₓ,a_{y} represent a transverse acceleration and a longitudinal acceleration of the automated driving commercial vehicle, respectively, and units are meters per quadratic second; ωₛ represents the yaw rate of the automated driving commercial vehicle, and a unit is radians per second; d_{rel_j}, v_{rel_j}, a_{rel_j} represent a relative distance, a relative speed and a relative acceleration between the automated driving commercial vehicle and a j-th vehicle, respectively, and units are meters, meters per second and meters per quadratic second, respectively, wherein j represents a serial number of the surrounding vehicles, and j=1, 2, 3, 4, 5, 6, represents vehicles in front of the automated driving commercial vehicle in the current lane, behind the automated driving commercial vehicle in the current lane, in front of the automated driving commercial vehicle in the left lane, behind the automated driving commercial vehicle in the left lane, in front of the automated driving commercial vehicle in the right lane, behind the automated driving commercial vehicle in the right lane;
(2) a motion space
defining a motion space covering both transverse and longitudinal driving policies as:
$${A}_{t} = [ {a}_{1} , {a}_{2} , {a}_{3} , {a}_{4} , {a}_{5} , {a}_{6} ] \qquad ( 2 )$$
where Aₜ represents a motion space at the time t, a₁, a₂, a₃ represent a left turn, a straight ahead, and a right turn, respectively, a₄, a₅, a₆ represent an acceleration, a maintaining speed, and a deceleration, respectively;
(3) a reward function
designing the reward function as:
$${R}_{t} = {r}_{1} + {r}_{2} + {r}_{3} + {r}_{4} + {r}_{5} + {r}_{6} \qquad ( 3 )$$
where Rₜ represents a total reward function at the time t, r₁, r₂, r₃, r₄, r₅, r₆ represent a forward anti-collision reward function, a backward anti-collision reward function, a side anti-collision reward function, an anti-rollover reward function, a driving smoothness reward function and a penalty function, respectively;
firstly, maintaining, with a propose of avoiding a forward collision, a reasonable safety distance between the automated driving commercial vehicle and a vehicle in front of a same lane, and defining the forward anti-collision reward function r₁ as:
$${r}_{1} = \{ \begin{matrix}{α}_{1} ( {x}_{rel \_ 1} - {D}_{f} ) & {x}_{rel \_ 1} \geq {D}_{f} \\ 0 & {x}_{rel \_ 1} < {D}_{f}\end{matrix} \qquad ( 4 )$$
where D_{f} represents a minimum forward safety distance and a unit is meters, α₁ represents a weight coefficient of the forward anti-collision reward function, and x_{rel_1} represents a relative distance between the automated driving commercial vehicle and the vehicle in front of the current lane and a unit is meters;
designing, by utilizing a time headway, a dynamic minimum forward safety distance as follows, considering that a reasonable minimum safety distance should take into account both a traffic efficiency and a traffic safety:
$${D}_{f} = {v}_{y} \cdot {β}_{TH} + \vert {v}_{y} - {v}_{rel \_ 1} \vert \cdot T + {L}_{min} \qquad ( 5 )$$
where β_{TH} represents the time headway and a unit is seconds, T represents a data sampling frequency and a unit is seconds, and Lₘᵢₙ is a critical distance and a unit is meters;
maintaining, with a propose of avoiding the backward collision, a reasonable safe distance between the automated driving commercial vehicle and a vehicle behind the same lane, and defining the backward anti-collision reward function r₂ as:
$${r}_{2} = \{ \begin{matrix}{α}_{2} ( {x}_{rel \_ 2} - {D}_{b} ) & {x}_{rel \_ 2} \geq {D}_{b} \\ 0 & {x}_{rel \_ 2} < {D}_{b}\end{matrix} \qquad ( 6 )$$
where D_{b} represents a minimum backward safety distance and a unit is meters, α₂ represents a weight coefficient of the backward anti-collision reward function, and x_{rel_2} represents a relative distance between the automated driving commercial vehicle and the vehicle behind the current lane and a unit is meters;
maintaining, with a purpose of avoiding the transverse collision, reasonable safe distances between the automated driving commercial vehicle and a vehicle in the left lane and a vehicle in the right lane, and defining the side anti-collision reward function r₃ as:
$${r}_{3} = \{ \begin{matrix}{\sum }_{i = 3}^{6} {α}_{3} ( {x}_{rel \_ j} - {D}_{s} ) & {x}_{rel \_ j} \geq {D}_{s} \\ 0 & {x}_{rel \_ j} < {D}_{s}\end{matrix} \qquad ( 7 )$$
where Dₛ represents a minimum side safety distance and a unit is meters, and
$${D}_{s} = 0.94 + \frac{3.6 \cdot {v}_{y} - 40}{200} ,$$
α₃ represents a weight coefficient of the side anti-collision reward function;
secondly, maintaining, with a purpose of avoiding a rollover accident, the automated driving commercial vehicle at a reasonable transverse acceleration, in a process of a curve running, a braking deceleration and the lane change, and defining the anti-rollover reward function r₄ as:
$${r}_{4} = \{ \begin{matrix}{α}_{4} ( {a}_{thr} - {a}_{x} ) & {a}_{x} \leq {a}_{thr} \\ 0 & {a}_{x} > {a}_{thr}\end{matrix} \qquad ( 8 )$$
where aₜₕᵣ represents a threshold of the transverse acceleration of the automated driving commercial vehicle, and a unit is meters per quadratic second, α₄ represents a weight coefficient of the anti-rollover reward function;
thirdly, defining, considering that a reasonable safe driving decision should not only ensure the driving safety, but also have a better driving smoothness and comfort, the driving smoothness reward function r₅ as:
$${r}_{5} = - {α}_{5} \cdot {\dot{a}}_{x} - {α}_{6} \cdot {\dot{a}}_{y} \qquad ( 9 )$$
where \dot{a}ₓ,\dot{a}_{y} represent a transverse jerk and a longitudinal jerk of the automated driving commercial vehicle, respectively, and units are meters per cubic second, α₅,α₆ represent weight coefficients of the driving smoothness reward function;
eventually, defining, by means of applying a negative feedback to avoid driving policies leading to the collision and the rollover accident, the penalty function r₆ as:
$${r}_{6} = \{ \begin{matrix}- 200 & a rollover occurred by the automated driving commercial vehicle \\ - 200 & a collision occurred by the automated driving commercial vehicle \\ 0 & no rollover or collision occurred by the automated driving commercial vehicle\end{matrix} \qquad ( 10 )$$
Sub-step 1.2, establishing a generator network based on “actor-critic”;
establishing, by utilizing an “actor-critic” framework, the generator network including a policy network and a criticism network, wherein in the policy network, state space information is taken as an input, and a motion decision, namely, the driving policies of the automated driving commercial vehicle are output; in the criticism network, the state space information and the motion decision are taken as inputs and a value for a current “state-motion” is output; specifically:
(1) designing a policy network part of the generator;
establishing, by utilizing a neural network with a plurality of fully connected layers, the policy network, firstly, inputting a normalized state quantity Sₜ into an input layer F1, a fully connected layer F2 and a fully connected layer F3 successively to obtain an output O₁, namely, a motion space Aₜ;
setting, considering that a dimension of the state space is 25, a number of neurons in a state input layer to be 25, a number of neurons in the fully connected layer F2 and the fully connected layer F3 to be 128 and 64, respectively, wherein activation functions of the fully connected layer F2 and the fully connected layer F3 are S-type functions, and an expression is
$$s ( x ) = \frac{1}{1 + {e}^{- x}} ;$$
(2) designing a criticism network part of the generator;
establishing, by utilizing the neural network with the plurality of fully connected layers, the criticism network, inputting the normalized state quantity Sₜ and the motion space Aₜ into a fully connected layer F4 and a fully connected layer F5 successively to obtain an output O₂, namely, the a Q function value Q(Sₜ,Aₜ);
setting the number of neurons in the fully connected layer F4 and the fully connected layer F5 to be 128 and 64, respectively, wherein the activation functions of both layers are S-type functions;
Sub-step 2, establishing a discriminator network;
taking, by the discriminator, an expert experience trajectory and a policy trajectory of the generator as inputs, and outputting, by determining differences between generated driving policies and the driving behaviors of the excellent drivers, a driving policy score Pₜ(τ), thereby implementing an optimization of the generator; establishing, by utilizing the deep neural network, the discriminator, in consideration of a strong nonlinear fitting ability, a strong processing ability of high dimensional data and a strong feature extraction ability of the deep neural network;
specifically, establishing, by utilizing the neural network with the plurality of fully connected layers, the discriminator, wherein the discriminator contains three fully connected layers F6, F7 and F8, an excitation function of each fully connected layer adopts a linear rectification function, an expression is f(x)=max(0,x);
Step 3, training the safe driving decision-making model of the automated driving commercial vehicle;
updating, by utilizing the GAIL algorithm, parameters for the safe driving decision-making model with a purpose of maximizing cumulative returns related to policy parameters, wherein a process of policy updating includes two stages, namely, an imitation learning stage and a reinforcement learning stage;
optimizing, by the discriminator, driving policies output by the generator by means of scoring, while taking, by the discriminator, differences between data generated by the network and expert data as bases for optimizing the policy network, in the imitation learning stage; guiding, by the criticism network, a learning direction of the safe driving decision-making model according to changes of the reward function, and further implementing the optimization of the driving policies output by the generator in the reinforcement learning stage; wherein a parameter updating method is specifically as follows:
Sub-step 1: initializing τ_{E}:π_{E}, initializing a policy parameter θ₀, a value function parameter ϕ₀, and a discriminator parameter ω₀;
where τ_{E} represents the expert trajectory data set constructed in Step 1 to represent the driving behaviors of excellent drivers, and τ_{E}={(S₁,A₁,R₁),(S₂,A₂,R₂), . . . , (Sₙ,Aₙ,Rₙ)}, n represents a number of the expert trajectories; τ_{E} represents a driving policy distribution corresponding to an expert trajectory τ_{E};
Sub-step 2: performing a 20000 iterative solution, wherein each iteration includes Sub-step 2.1 to Sub-step 2.5, specifically:
Sub-step 2.1: generating, by the policy network, a driving trajectory τ′_{E}, to form a trajectory set Pₜ expressed as Pₜ={τ′_{E}};
Sub-step 2.2: sampling the expert trajectory, and expressing the “trajectory-policy distribution” after sampling as τᵢ:π_{θ}_{ᵢ}, where τᵢ represents an expert trajectory sampled at the time i, and π_{θ}_{ᵢ} represents a strategy corresponding to the expert trajectory sampled at the time i;
Sub-step 2.3: updating, by utilizing a gradient ∇_{cri}, network parameters for the discriminator;
$${∇}_{cri} = {\hat{E}}_{{τ}_{i}} [ {∇}_{t} log ( {P}_{t} ( {S}_{t} , {A}_{t} ) ) ] + {\hat{E}}_{{τ}_{E}} [ {∇}_{t} log ( 1 - {P}_{t} ( {S}_{t} , {A}_{t} ) ) ] \qquad ( 11 )$$
where Pₜ(Sₜ,Aₜ) represents an output of the discriminator at the time t, namely, a probability that a current trajectory is the expert trajectory; Ê_{τ}_{ᵢ} represents an average reward of generating the driving trajectory; ∇ₜ represents a gradient at the time t; Ê_{τ}_{_{E}} represents an average reward obtained by the expert trajectory;
Sub-step 2.4: updating a policy network parameter;
Sub-step 2.5: updating a value function parameter by utilizing a Formula (12);
$${ϕ}_{t + 1} = arg {min}_{ϕ} \frac{1}{\vert {P}_{t} ( {S}_{t} , {A}_{t} ) \vert \cdot T} {\sum }_{{τ}_{E} ∈ {P}_{t}} {{\sum }_{t = 0}^{T} [ {V}_{ϕ} ( {S}_{t} ) - {\hat{R}}_{t} ]}^{2} \qquad ( 12 )$$
where ϕₜ₊₁ represents a value function parameter at a time t+1, V_{ϕ}(Sₜ) represents a value function when the state space is Sₜ, and \hat{R}ₜ represents a reward function to be performed at the time t;
Sub-step 3: terminating, when a number of training iterations reaches 20000, the loop;
Sub-step 4: outputting, by utilizing the safe driving decision-making model, decision policies;
inputting, after completing the training of the safe driving decision-making model, the state space information collected by the sensors into the safe driving decision-making model outputting an advanced driving decision such as a steering, an acceleration, and a deceleration reasonably and safely, thereby implementing a safe driving decision of a vehicle with highly humanoid level and effectively ensuring a driving safety of the automated driving commercial vehicle.
